(19) United States
(12) Patent Application Publication
(10) Pub. No.: US 2022/0223574 A1
(43) Pub. Date: Jul. 14, 2022

(54) PACKAGE STRUCTURE AND PACKAGE METHOD FOR CAVITY DEVICE GROUP

(71) Applicant: JCET GROUP CO., LTD., Wuxi City, Jiangsu Provinces (CN)

(72) Inventors: YAOJIAN LIN, Wuxi City, Jiangsu Province (CN); SHUO LIU, Wuxi City, Jiangsu Province (CN); XUEQING CHEN, Wuxi City, Jiangsu Province (CN); SHASHA ZHOU, Wuxi City, Jiangsu Province (CN); CHENYE HE, Wuxi City, Jiangsu Province (CN); CHEN XU, Wuxi City, Jiangsu Province (CN)

(21) Appl. No.: 17/613,061

(22) PCT Filed: May 25, 2020
(86) PCT No.: PCT/CN2020/092030

§ 371 Date: Nov. 20, 2021

(30) Foreign Application Priority Data
Nov. 11, 2019 (CN) 201911095882.3

(51) Int. Cl. H01L 25/16; H01L 23/29; H01L 23/31; H01L 21/56

(52) U.S. Cl. CPC H01L 25/165; H01L 23/293; H01L 24/16; H01L 23/3142; H01L 21/565; H01L 23/3128

(57) ABSTRACT

The present invention relates to a package structure and package method for a cavity device group. The package structure includes a substrate, the substrate including a first substrate surface and a second substrate surface which face each other, wherein a first cavity device group is provided on the first substrate surface. The package structure further includes: a first sealing layer encapsulating the first cavity device group; and a first plastic package layer encapsulating the first sealing layer, wherein the flowability of a sealing material of the first sealing layer is less than that of a plastic package material of the first plastic package layer. The problems of device damage and functional failure of a cavity device group in the existing package structure because it is likely affected by a mold flow pressure in the injection molding process can be solved, while the function and miniaturization of a module are maintained.

### CROSS-REFERENCE TO RELATED APPLICATION

The present application is based on and claims priority to Chinese Patent Application No. 201911095882.3, filed on Nov. 11, 2019 and entitled “PACKAGE STRUCTURE AND PACKAGE METHOD FOR CAVITY DEVICE GROUP”, the disclosure of which is herein incorporated by reference in its entirety.

### TECHNICAL FIELD

The present invention relates to the field of packaging technologies, and more particularly to a package structure and package method for a cavity device group.

### BACKGROUND

In the current system-in-package structure, a cavity device such as a filter is more sensitive to a plastic package pressure due to its cavity. Therefore, when a module product is plastically packaged with an injection molding material in the subsequent process, a body structure of the cavity device such as the filter will collapse in response to the failure to withstand a mold flow pressure during the injection molding process, or deform or crack in the subsequent reliability test after the cavity surface contacts a residual stress of a plastic package material, resulting in functional failure of the cavity device such as the filter because the internal cavity is damaged under a pressure.

Therefore, it is necessary to improve related technologies to solve the above-mentioned problems, so as to improve the overall reliability and packaging yield of a package structure including a cavity device, and to maintain the function and miniaturization of a module.

### SUMMARY

Objectives of the present invention are to provide a package structure and package method for a cavity device group, so as to solve the problems of device damage and functional failure of a cavity device group such as a filter in an existing package structure because it is likely affected by a mold flow pressure in the injection molding process, and meanwhile, ensure functions of a radio-frequency front-end module.

In order to fulfill one of the above objectives of the present invention, an embodiment of the present invention provides a package structure for a cavity device group. The package structure includes a substrate, wherein the substrate includes a first substrate surface and a second substrate surface which face each other, and a first cavity device group is provided on the first substrate surface; and the package structure further includes a first sealing layer encapsulating the first cavity device group, and a first plastic package layer encapsulating the first sealing layer, wherein the flowability of a sealing material of the first sealing layer is less than that of a plastic package material of the first plastic package layer.

As a further improvement of an embodiment of the present invention, the first sealing layer also covers the first substrate surface.

As a further improvement of an embodiment of the present invention, a second cavity device group and a second sealing layer are provided on the second substrate surface, wherein the second sealing layer encapsulates the second cavity device group.

As a further improvement of an embodiment of the present invention, the second substrate surface is also covered with a second plastic package layer; the second plastic package layer encapsulates the second sealing layer; and the flowability of a sealing material of the second sealing layer is less than that of a plastic package material of the second plastic package layer.

As a further improvement of an embodiment of the present invention, a dummy wafer is also arranged on the edge of the first substrate surface, and sequentially encapsulated by the first sealing layer and the first plastic package layer.

As a further improvement of an embodiment of the present invention, a passive element is provided on the first substrate surface, and encapsulated by the first sealing layer and the first plastic package layer sequentially.

As a further improvement of an embodiment of the present invention, an electrical and thermal conduction structure is provided on the second substrate surface, and at least partially encapsulated by the second plastic package layer.

An embodiment of the present invention further provides a package method for a cavity device group. The package method includes the following steps: providing a first cavity device group on a first substrate surface; providing a first sealing layer on the outer periphery of the first cavity device group, such that the first cavity device group is encapsulated by the first sealing layer; and performing plastic packaging on the first substrate surface to form a first plastic package layer, such that the first sealing layer is encapsulated by the first plastic package layer, wherein the flowability of a sealing material of the first sealing layer is less than that of a plastic package material of the first plastic package layer.

As a further improvement of an embodiment of the present invention, the method further includes: providing a first sealing layer on the outer periphery of the first cavity device group and the first substrate surface, such that the first sealing layer covers the first substrate surface and encapsulates the first cavity device group.

As a further improvement of an embodiment of the present invention, the method further includes: providing a second cavity device group and a second sealing layer on the second substrate surface, such that the second cavity device group is encapsulated by the second sealing layer.

As a further improvement of an embodiment of the present invention, the method further includes: covering the second substrate surface with a second plastic package layer, such that the second sealing layer is encapsulated by the second plastic package layer, wherein the flowability of a sealing material of the second sealing layer is less than that of a plastic package material of the second plastic package layer.

As a further improvement of an embodiment of the present invention, the method further includes: providing a dummy wafer on the edge of the first substrate surface, such that the dummy wafer is encapsulated by the first sealing layer and the first plastic package layer sequentially.

As a further improvement of an embodiment of the present invention, the method further includes: providing a passive element on the first substrate surface, such that the passive element is encapsulated by the first sealing layer and the first plastic package layer sequentially.

As a further improvement of an embodiment of the present invention, the method further includes: thinning the first plastic package layer.

As a further improvement of an embodiment of the present invention, the method further includes: thinning the second plastic package layer.

Compared with the prior art, the present invention has the following beneficial effects. In the package structure, the sealing layer is provided between the cavity device group and the plastic package layer to encapsulate the cavity device group, without contacting a cavity area of a cavity device. Meanwhile, the flowability of the sealing material of the sealing layer is less than that of the plastic package material of the plastic package layer. Therefore, the cavity device group can be protected against damage from a plastic molding pressure and functional failure caused by a change in residual stress of other non-device materials, thereby ultimately improving the overall reliability and the package yield of the package structure, and maintaining the function and miniaturization of a module.

### BRIEF DESCRIPTION OF THE DRAWINGS

FIG. 1 is a schematic structural diagram of a package structure in Embodiment 1 of the present invention;

FIGS. 2a and 2b are schematic structural diagrams of a first cavity device group in Embodiment 1 of the present invention;

FIG. 3 is a schematic structural diagram of a package structure in Embodiment 2 of the present invention;

FIG. 4 is a schematic structural diagram of a second cavity device group in Embodiment 2 of the present invention.

FIG. 5 is a schematic structural diagram of a package structure in another embodiment of the present invention;

FIG. 6 is a schematic structural diagram of a package structure in yet another embodiment of the present invention;

FIG. 7 is a schematic structural diagram of a conventional device group in yet another embodiment of the present invention;

FIG. 8 is a schematic structural diagram of a package structure in Embodiment 3 of the present invention;

FIGS. 9a and 9b are schematic structural diagrams of a dummy wafer and a passive element in Embodiment 3 of the present invention;

FIG. 10 is a schematic structural diagram of a package structure in Embodiment 4 of the present invention; and

FIG. 11 is a schematic flowchart of a package method for a package structure in an embodiment of the present invention.

### DETAILED DESCRIPTION

In order to make the objectives, technical solutions, and advantages of the present invention clearer, the technical solutions of the present invention will be clearly and completely described below in conjunction with the specific embodiments of the present invention and the corresponding drawings. Obviously, the described embodiments are only a part of the embodiments of the present invention, rather than all of the embodiments. Based on the embodiments in this disclosure, all other embodiments obtained by those of ordinary skill in the art without creative work shall fall within the protection scope of this disclosure.

The following describes the embodiments of the present invention in detail. Examples of the embodiments are shown in the accompanying drawings, in which the same or similar reference numerals indicate the same or similar elements or elements with the same or similar functions through the whole text. The following embodiments described with reference to the accompanying drawings are exemplary, and are only used to explain the present invention, but should not be understood as limiting the same.

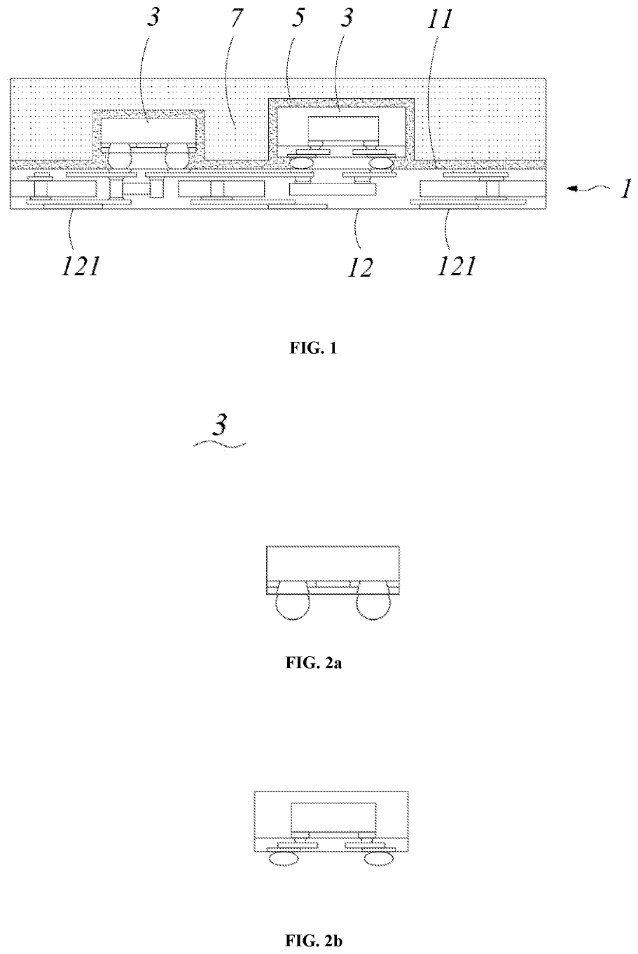

As shown in FIG. 1 to FIG. 6, an embodiment of the present invention provides a package structure for a cavity device group. The package structure includes a substrate 1. The substrate 1 includes a first substrate surface 11 and a second substrate surface 12 which face each other. A first cavity device group 3 is provided on the first substrate surface. The package structure further includes a first sealing layer 5 which covers the first substrate surface 11 and encapsulates the first cavity device group 3, and a first plastic package layer 7 which encapsulates the first sealing layer 5, wherein the flowability of a sealing material of the first sealing layer 5 is less than that of a plastic package material of the first plastic package layer 7.

Specifically, in the package structure, the substrate 1 is a device-embedded substrate in which a passive component and an IC chip are embedded. The embedded substrate 1 includes two surfaces which face each other. The first cavity device group 3, which is sensitive to a mold flow pressure during plastic package, is provided on a first surface of the substrate 1 and is electrically connected to the substrate 1. Moreover, in addition to the device-embedded substrate, the substrate 1 may also be a non-device-embedded substrate. Embedded devices include a passive device, a chip and the like.

In order to prevent the mold flow pressure in the subsequent plastic package process from damaging the cavity device, prior to the plastic package process, the first substrate surface 11 is covered with a first sealing layer 5 in advance. The first sealing layer 5 encapsulates the first cavity device group 3, that is, the first sealing layer 5 encapsulates all the cavity devices on the first substrate surface 11. The first sealing layer 5 is encapsulated by the first plastic package layer 7, that is, the first cavity device group 3 is encapsulated by the first sealing layer 5 and the first plastic package layer 7 sequentially. Meanwhile, the flowability of the sealing material of the first sealing layer 5 is less than that of the plastic package material in the subsequent process. In this way, the sealing material of the first sealing layer 5 does not flow into or contact a pressure sensitive area of the cavity device, and thus functions to protect the first cavity device group 3. In the plastic package process, the mold flow pressure generated by the first plastic package layer 7 is also buffered in time by the first sealing layer 5 to further protect the first cavity device group 3.

The first sealing layer 5 may be of a structure of a single material or a structure of multiple layers of materials. An inner layer of the first sealing layer 5 is made of an insulation material, and an outer layer of the first sealing layer 5 is made of a conductive material. For example, the inner layer is made of an insulation sealing material at the edge of the device, and the outer layer is made of a Cu or Ag conductive spray shielding material.

Optionally, the first cavity device group 3 includes at least one cavity device. That is, the number of the cavity devices is not limited, and there may be a plurality of cavity devices inside the first cavity device group 3. A package form of each cavity device is not limited, and it may be system-in-package, wafer-level package (WLP), chip-scale package or the like, or may be land grid array (LGA) package, ball grid array (BGA) package, or the like. Therefore, the first cavity device group 3 together with the passive component and IC chip in the substrate 1 and a substrate circuit are organized to form a radio-frequency front-end SiP system.

As shown in FIGS. 2a and 2b, the first cavity device group 3 includes cavity devices in two package forms, one being in a WLP form, and the other being in an LGA or BGA package form.

Optionally, the first sealing layer 5 may be processed by using a vacuum or low-pressure film laminating process, and may be made of an organic composite film with a filler. Alternatively, the first sealing layer 5 is processed by performing vacuum and low-pressure glue dispensing using organic epoxy composite high-viscosity paste to seal the edge of the device and in conjunction with integral spraying. The sprayed material may be an electromagnetic shielding material, such as a conductive sprayed material in which Cu and Ag are combined. The first plastic package layer 7 may be processed by using a conventional injection molding process or a hot pressing process, and may be made of a plastic package material with better flowability.

Optionally, due to different processing techniques, the first sealing layer 5 may only encapsulate the first cavity device group 3 without covering the first substrate surface 11, or may encapsulate the first cavity device group 3 while covering the first substrate surface 11.

Optionally, a device or passive element 93 with a large center distance and less I/O, such as a large inductor, which is unlikely to bridge and short-circuit, may be provided on the first substrate surface 11 or the second substrate surface 12. When the passive element 93 such as the large inductor is provided on the first substrate surface 11, it may also be sequentially encapsulated by the first sealing layer 5 and the first plastic package layer 7, or only by the first plastic package layer 7.

Optionally, other thinner devices and chips may also be buried inside the substrate 1. That is, the substrate 1 may be hollowed out with a hollowed-out portion being embedded with these thinner devices, or these thinner devices may be integrally formed with the substrate 1, thereby saving the overall space of the package structure and improving the package integration.

In addition, some other devices, such as other passive devices (e.g., passive components or IC chips), which are sensitive to pin short-circuiting but not sensitive to pressure, may be provided on the second substrate surface 12 or in the substrate.

Further, the first sealing layer 5 further covers the first substrate surface 11.

In response to a processing method such as film lamination, the first sealing layer 5 may cover the entire first substrate surface 11 and completely encapsulate the first cavity device group 3. Therefore, the first sealing layer 5 may be processed and set conveniently and quickly.

Further, a second cavity device group 2 and a second sealing layer 4 are provided on the second substrate surface 12, and the second sealing layer 4 encapsulates the second cavity device group 2.

Further, the second substrate surface 12 is further covered with a second plastic package layer 6. The second plastic package layer 6 encapsulates the second sealing layer 4, wherein the flowability of a sealing material of the second sealing layer 4 is less than that of a plastic package material of the second plastic package layer 6.

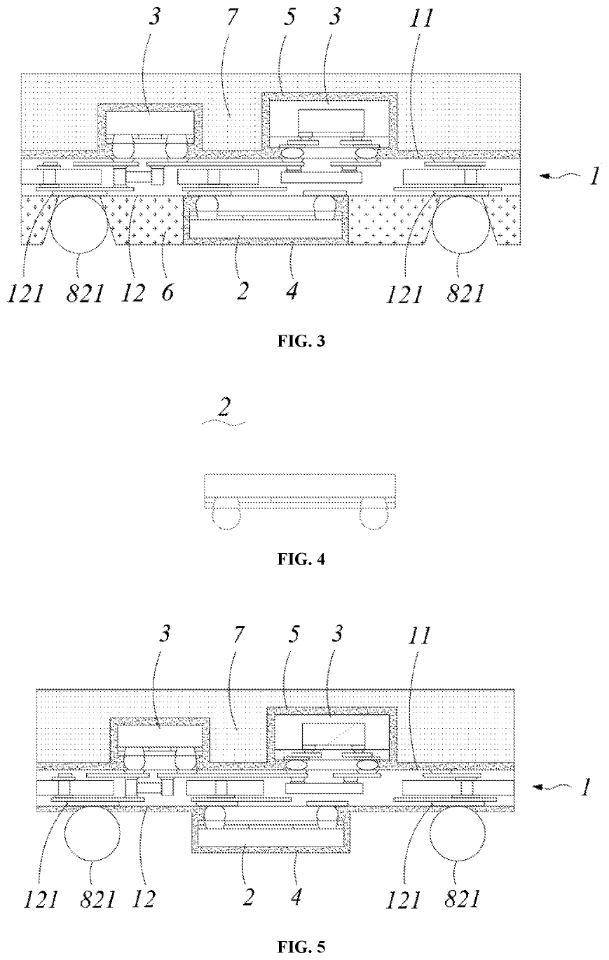

As shown in FIGS. 3 and 4, a second cavity device group 2, which is sensitive to a mold flow pressure during plastic package, is further provided on the second substrate surface. The second cavity device group 2 is encapsulated by the second sealing layer 4. The sealing material of the second sealing layer 4 cannot flow into or contact a pressure sensitive area of the cavity device due to low flowability, and thus can function to protect the second cavity device group 2.

Meanwhile, a solder ball 821 may further be provided on the second substrate surface for further electrical connection with other substrate or structure.

The second sealing layer 4 is optional, which may be selected according to specific conditions of the second substrate surface 12. For example, when other conventional device groups that are not sensitive to a molding pressure are provided on the second substrate surface 12, the second substrate surface 12 may be free of a second sealing layer 4, and only needs to be covered with a second plastic package layer 6.

In addition, the second substrate surface 12 may further be covered with another second plastic package layer 6. The second plastic package layer 6 encapsulates the second sealing layer 4, without contacting the cavity area of the cavity device. Meanwhile, in response to material selection, it needs to be ensured that the flowability of the sealing material of the first sealing layer 5 is less than that of the plastic package material of the second plastic package layer 6. Therefore, during the plastic package process, the mold flow pressure generated by the second plastic package layer 6 is buffered in time by the second sealing layer 4, and the second sealing layer 4 further functions to protect the second cavity device group 2.

Meanwhile, when the solder ball 821 is provided on the second substrate surface 12, at least part of the solder ball 821 is exposed from the second plastic package layer 6 for further electrical connection.

Here, the second plastic package layer 6 encapsulating the second sealing layer 4 means that the second plastic package layer 6 may completely cover all the outer peripheral surfaces of the second sealing layer 4; or the second plastic package layer 6 may cover the surrounding surface of the second sealing layer 4. The second sealing layer 4 is optional and may be selected according to specific conditions of the second substrate surface 12.

The second sealing layer 4 may be made of an organic composite film with a filler. Alternatively, the second sealing layer 4 is processed by performing vacuum and low-pressure glue dispensing using organic epoxy composite high-viscosity paste to seal the edge of the device and then in conjunction with local spraying on the substrate. The sprayed material may be an electromagnetic shielding material, such as a conductive sprayed material in which Cu and Ag are combined.

In another embodiment of the package structure, the second sealing layer 4 may also cover the entire second substrate surface 12 in addition to encapsulating the second cavity device group 2. As shown in FIG. 5, the second substrate surface 12 may also be covered only with one second sealing layer 4. Similarly, the second sealing layer 4 may be made of an organic composite film with a filler. Alternatively, the second sealing layer 4 is processed by performing vacuum and low-pressure glue dispensing using organic epoxy composite high-viscosity paste to seal the edge of the device and then in conjunction with local spraying on the substrate. The sprayed material may be an electromagnetic shielding material, such as a conductive sprayed material in which Cu and Ag are combined, or may be an insulation material.

When the second sealing layer 4 covers the entire second substrate surface 12, it is necessary to expose a pad 121 on the second substrate surface 12 through a laser drilling process, such that the pad 121 is electrically connected to the solder ball 821 embedded later, without causing any short circuit.

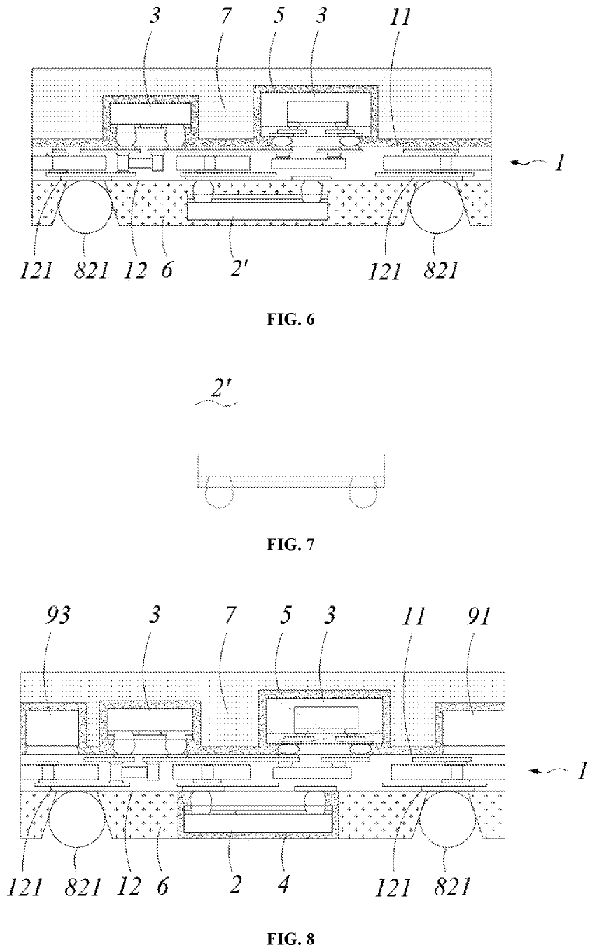

As shown in FIGS. 6 and 7, in yet another embodiment of the package structure, the second sealing layer may be absent, and only one second plastic package layer 6 is required for coverage. Specifically, other conventional device group 2′, such as a WLP device, that is not sensitive to a molding pressure, may further be provided on the second substrate surface 12. At this time, the second substrate surface 12 only needs to be covered with one second plastic package layer 6 to protect the conventional device group 2′.

Optionally, when the second substrate surface 12 is covered with the second plastic package layer 6, the solder ball 821 may also be exposed through a laser drilling process, such that the solder ball 821 is electrically connected to other substrate 1 or structure.

Further, a dummy wafer 91 is further provided on the edge of the first substrate surface 91, such that the dummy wafer is sequentially encapsulated by the first sealing layer 5 and the first plastic package layer 7. The dummy wafer 91 may be made of a material such as silicon, ceramic or glass; or may be made of PCB, a substrate material or different plastic package material; or may also be made of metal, such as a metal frame made of a copper material.

Further, a passive element 93 is further provided on the first substrate surface 11, such that the passive element 93 is sequentially encapsulated by the first sealing layer 5 and the first plastic package layer 7.

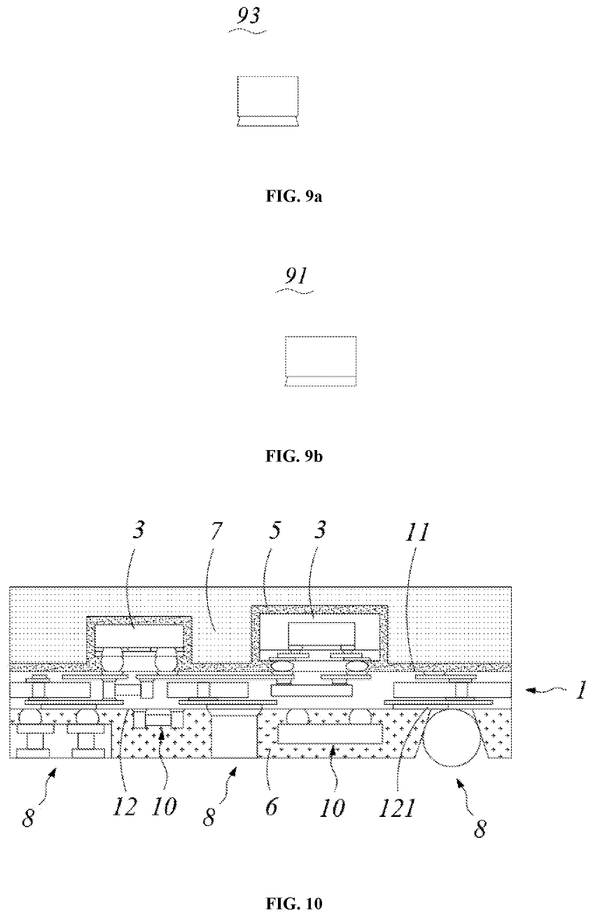

As shown in FIGS. 8, 9a and 9b, the package structure is further provided with a dummy wafer 91. The dummy wafer 91 is a circuit-free chip made of a silicon material. The dummy wafer 91 may be provided on the edge of the first substrate surface 11 and also sequentially encapsulated or covered by the first sealing layer 5 and the first plastic package layer 7. When the first sealing layer 5 and the first plastic package layer 7 are cured, the dummy wafer 91 can effectively balance and relieve a shrinkage stress caused by material curing, and prevent the first cavity device group 3 from being damaged by such stress.

The dummy wafer 91 may be made of a material such as silicon, ceramic or glass; or may be made of PCB, a substrate material or different plastic package material; or may also be made of metal, such as a metal frame made of a copper material.

In addition, a passive element 93, such as a large inductor may further be provided on the first substrate surface 11, and sequentially encapsulated by the first sealing layer 5 and the first plastic package layer 7, which can also protect the passive element 93 and balance and relieve a curing stress.

Meanwhile, isolating glue may also be provided between the lower surface of the passive element 93 and the first substrate surface 11 to prevent pins from being short-circuited.

Optionally, the dummy wafer 91 may also be provided in a non-edge area of the substrate 1, e.g., in a larger separation area between respective devices disposed in the center of the substrate 1, thereby balancing and relieving the stress caused by material curing.

Further, an electrical and thermal conduction structure 8 and a second plastic package layer 6 are further provided on the second substrate surface 12, and the second plastic package layer 6 encapsulates at least part of the electrical and thermal conduction structure 8.

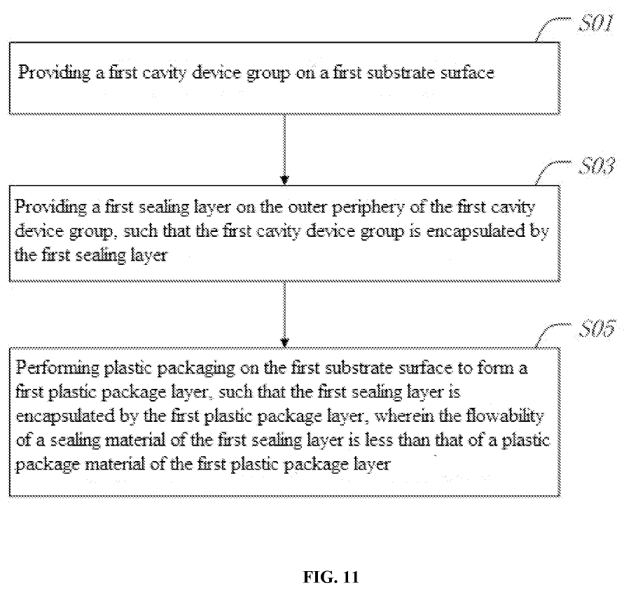

As shown in FIG. 10, an electrical and thermal conduction structure 8 may further be provided on the second substrate surface 12, and is encapsulated by the second plastic package layer 6. The electrical and thermal conduction structure 8 is at least partially exposed to facilitate further electrical connection between the second substrate surface 12 and other substrate or structure. The electrical and thermal conduction structure 8 is a 3D electrical and thermal connection structure. The 3D electrical and thermal conduction structure includes connection structures such as a PCB interposer, a copper pillar, and a solder ball.

In addition, a non-pressure-sensitive device 10, which may be a non-pressure-sensitive cavity device, an IC chip, a passive component or the like, may further be provided on the second substrate surface 12. Meanwhile, a device (e.g., a passive device in which isolating glue is pre-dispensed) in which pins are unlikely to be short-circuited is provided on the first substrate surface 11.

During the processing, the non-pressure-sensitive device 10 and the 3D electrical and thermal conduction structure 8 may be bonded on the second substrate surface 12, and then the non-pressure-sensitive device 10 is encapsulated by the second plastic package layer 6 and the 3D electrical and thermal conduction structure 8 is at least partially exposed by means of laser drilling and the like, thereby facilitating further electrical connection.

To facilitate understanding, the following embodiments are described in detail.

### Embodiment 1

As shown in FIGS. 1, 2a and 2b, this embodiment provides a package structure for a cavity device group. The package structure includes a substrate 1, a first cavity device group 3, a first sealing layer 5 and a first plastic package layer 7. The substrate 1 is a device-embedded substrate in which a passive component and an IC chip are embedded. The embedded substrate 1 includes a first substrate surface 11 and a second substrate surface 12. The first cavity device group 3, which is sensitive to a mold flow pressure during plastic package, is provided on the first substrate surface 11. The first cavity device group 3 is encapsulated by the first sealing layer 5 and the first plastic package layer 7 sequentially, and the first sealing layer 5 covers the entire first substrate surface 11. The flowability of a sealing material of the first sealing layer 5 is less than that of a plastic package material of the first plastic package layer 7. Therefore, during the plastic package process, a mold flow pressure generated by the first plastic package layer 7 is buffered and reduced in time by the first sealing layer 5, such that the first cavity device group 3 can be protected from being damaged by such mold flow pressure. The dummy wafer 91 may be made of a material such as silicon, ceramic or glass; or may be made of PCB, a substrate material or different plastic package material; or may also be made of metal, such as a metal frame made of a copper material.

### Embodiment 2

As shown in FIGS. 3 and 4, a package structure for the cavity device group in this embodiment differs from Embodiment 1 in that: the package structure further includes a second cavity device group 2, a second sealing layer 4, a second plastic package layer 6 and a solder ball 821. The second cavity device group 2, which is sensitive to a mold flow pressure during plastic package, is provided on the second substrate surface 12. The second sealing layer 4 encapsulates the second cavity device group 2, and the second plastic package layer 6 covers the second substrate surface 12 and encapsulates the second sealing layer 4. The solder ball 821 disposed in the second plastic package layer 6 is electrically connected to a pad 121 on the second substrate surface 12, and the lower part of the solder ball 821 is exposed by means of drilling, thereby facilitating the subsequent electric connection between the entire package structure and other substrate 1 or structure. As above, by means of such setting, a mold flow pressure generated by the first plastic package layer 6 during the plastic package process is buffered and reduced in time by the second sealing layer 4. The second sealing layer 4 functions to protect the second cavity device group 2.

### Embodiment 3

As shown in FIGS. 8, 9a and 9b, a package structure for the cavity device group in this embodiment differs from Embodiment 2 in that: the package structure further includes a dummy wafer 91 and a passive element 93. The dummy wafer 91 is provided on the edge of the first substrate surface 11 and is also encapsulated by the first sealing layer 5 and the first plastic package layer 7 sequentially. The passive element 93 is a large-inductance element, which is also encapsulated by the first sealing layer 5 and the first plastic package layer 7 sequentially. In this way, the dummy wafer 91 can effectively balance and relieve a shrinkage stress generated in response to the curing of a sealing material and a plastic package material, and prevent the first cavity device group 3 from being damaged by such shrinkage stress.

### Embodiment 4

As shown in FIG. 10, a package structure for the cavity device group in this embodiment differs from Embodiment 1 in that: the package structure further includes a second plastic package layer 6 and an electrical and thermal conduction structure 8 which is encapsulated by the second plastic package layer 6. The electrical and thermal conduction structure 8 is at least partially exposed to facilitate further electrical connection between the second substrate surface 12 and other substrate or structure. The electrical and thermal conduction structure 8 is a 3D electrical and thermal connection structure. The 3D electrical and thermal conduction structure includes connection structures such as a PCB interposer, a copper pillar, and a solder ball.

In addition, a non-pressure-sensitive device 10, which may be a non-pressure-sensitive cavity device, an IC chip, a passive component or the like, may further be provided on the second substrate surface 12. Meanwhile, a device (e.g., a passive device in which isolating glue is pre-dispensed) in which pins are unlikely to be short-circuited, is provided on the first substrate surface 11.

As shown in FIG. 11, an embodiment of the present invention further provides a package method for a cavity device group. The package method includes the following steps, which are described in detail below.

In S01, a first cavity device group 3 is provided on a first substrate surface 11.

In S03, a first sealing layer 5 is provided on the outer periphery of the first cavity device group 3, such that the first cavity device group 3 is encapsulated by the first sealing layer 5.

In S05, the first substrate surface 11 is subjected to plastic package to form a first plastic package layer 7, such that the first sealing layer 5 is encapsulated by the first plastic package layer 7, wherein the flowability of a sealing material of the first sealing layer 5 is less than that of a plastic package material of the first plastic package layer 7.

Specifically, in the package structure, the substrate 1 includes two surfaces which face each other, i.e., the first substrate surface 11 and a second substrate surface 12.

First, the first cavity device group 3, which is sensitive to a mold flow pressure during plastic package, is provided on the first substrate surface 11, such that the first cavity device group 3 is electrically connected to the first substrate surface 11. After the setting is completed, the first sealing layer 5 is provided on the outer periphery of the first cavity device group 3, such that the first cavity device group 3 is encapsulated by the first sealing layer 5. The sealing material of the first sealing layer 5 cannot flow into or contact a pressure sensitive area of a cavity device due to low flowability. The first sealing layer 5 may function to protect the first cavity device group 3.

Then, the first plastic package layer 7 is formed by performing plastic packaging on the first substrate surface 11 to encapsulate the first sealing layer 5. Meanwhile, it needs to be ensured that the flowability of the sealing material of the first sealing layer 5 is less than that of the plastic package material of the second plastic package layer 7. Therefore, during the plastic package process, a mold flow pressure generated by the first plastic package layer 7 is buffered in time by the first sealing layer 5 to further protect the first cavity device group 3, thereby preventing the first cavity device group 3 from being affected by such mold flow pressure during plastic package.

Optionally, the first cavity device group 3 includes one or more cavity devices. A package form of each cavity device is not limited, and it may be system-in-package, wafer-level package (WLP), chip-scale package or the like; or may be land grid array (LGA) package, ball grid array (BGA) package, or the like.

Optionally, the first sealing layer 5 may be processed by using a vacuum or low-pressure film laminating process, and may be made of an organic composite film with a filler. Alternatively, the first sealing layer 5 is processed by performing vacuum and low-pressure glue dispensing using organic epoxy composite high-viscosity paste and then selecting a spraying process. The first plastic package layer 7 may be processed by using a conventional injection molding process or a hot pressing process, and may be made of a plastic package material with better flowability.

Optionally, due to different processing techniques, the first sealing layer 5 may only encapsulate the first cavity device group 3 without covering the first substrate surface 11; or may encapsulate the first cavity device group 3 while covering the first substrate surface 11.

Optionally, a device or passive element 93 with a large center distance and less I/O, such as a large inductor, which is unlikely to bridge and short-circuit, may be provided on the first substrate surface 11 or the second substrate surface 12. When the passive element 93 such as the large inductor is provided on the first substrate surface 11, it may also be encapsulated by the first sealing layer 5 and the first plastic package layer 7 sequentially, or only by the first plastic package layer 7.

Optionally, other thinner devices and chips may also be buried inside the substrate 1. That is, the substrate 1 may be hollowed out with a hollowed-out portion being embedded with these thinner devices, or these thinner devices may be integrally formed with the substrate 1, thereby saving the overall space of the package structure and improving the package integration.

Further, step S03 specifically includes:

S031: providing a first sealing layer 5 on the outer periphery of the first cavity device group and the first substrate surface 11, such that the first sealing layer 5 covers the first substrate surface 11 and encapsulates the first cavity device group 3.

After the first cavity device group 3 is provided on the first substrate surface 11, the first sealing layer 5 may be provided on the first substrate surface 11 through a process such as film lamination, such that the first sealing layer 5 covers the first substrate surface 11 and encapsulates the first cavity device group 3 at the same time. In addition, the first sealing layer 5 does not contact a cavity area of the cavity device, such that the first sealing layer 5 is quickly formed to protect the first cavity device group 3.

The first sealing layer 5 may be of a structure of a single material or a structure of multiple layers of materials. An inner layer of the first sealing layer 5 is made of an insulation material, and an outer layer of the first sealing layer 5 is made of a conductive material. For example, the inner layer is made of an insulation sealing material at the edge of the device, and the outer layer is made of a Cu or Ag conductive spray shielding material.

Further, before step S01 or after step S05, the method further includes:

S006: providing a second cavity device group 2 and a second sealing layer 4 on the second substrate surface 12, such that the second cavity device group 2 is encapsulated by the second sealing layer 4.

Further, after step S006, the method specifically includes:

S007: covering the second substrate surface 12 with a second plastic package layer 6, such that the second sealing layer 4 is encapsulated by the second plastic package layer 6, wherein the flowability of a sealing material of the second sealing layer 4 is less than that of a plastic package material of the second plastic package layer 6.

Specifically, the second cavity device group 2, the second sealing layer 4 and the second plastic package layer 6 may further be provided on the second substrate surface 12. In addition, the second substrate surface 12 may be processed before the first substrate surface 11, or may be processed after the first substrate surface 11, and the process sequence is not limited.

Similarly, the second cavity device group 2, which is sensitive to a mold flow pressure during plastic package, may be provided on the second substrate surface 12 first. Then, the second sealing layer 4 is provided on the outer periphery of the second cavity device group 2. The sealing material of the second sealing layer 4 cannot flow into or contact a pressure sensitive area of the cavity device due to low flowability, and thus can function to protect the second cavity device group 2.

Meanwhile, a solder ball 821 may further be provided on the second substrate surface 12 for further electrical connection with other substrate 1 or structure.

The second sealing layer 4 is optional, which may be selected according to the specific conditions of the second substrate surface 12. For example, when other conventional device groups that are not sensitive to a molding pressure are provided on the second substrate surface 12, the second substrate surface 12 may be free of a second sealing layer 4, and only needs to be covered with a second plastic package layer 6.

In addition, the second substrate surface 12 may further continue to be covered with a second plastic package layer 6, the second plastic package layer 6 encapsulating the second sealing layer 4. Meanwhile, in response to material selection, it needs to be ensured that the flowability of the sealing material of the first sealing layer 5 is less than that of the plastic package material of the second plastic package layer 6. Therefore, during the plastic package process, a mold flow pressure generated by the second plastic package layer 6 is buffered in time by the second sealing layer 4, and the second sealing layer 4 further functions to protect the second cavity device group 2.

Meanwhile, when the solder ball 821 is provided on the second substrate surface 12, at least part of the solder ball 821 is exposed from the second plastic package layer 6 for further electrical connection.

Optionally, the second sealing layer 4 may further cover the entire second substrate surface 12 in addition to encapsulating the second cavity device group 2. When the second sealing layer 4 covers the entire second substrate surface 12, it is necessary to expose a pad 121 on the second substrate surface 12 through a laser drilling process, such that the pad 121 is electrically connected to the solder ball 821 embedded later.

Optionally, when the second substrate surface 12 is covered with the second plastic package layer 6, the solder ball 821 may also be exposed through a laser drilling process, such that the solder ball 821 is electrically connected to other substrate 1 or structure.

Further, after step S01, the method further includes:

S021: providing a dummy wafer 91 on the edge of the first substrate surface 11, such that the dummy wafer 91 is encapsulated by the first sealing layer 5 and the first plastic package layer 7 sequentially.

Further, after step S01, the method further includes:

S022: providing a passive element 93 on the first substrate surface 11, such that the passive element 93 is encapsulated by the first sealing layer 5 and the first plastic package layer 7 sequentially.

Specifically, the dummy wafer 91 and the passive element 93 may further be provided on the first substrate surface 11. After the first cavity device group 3 is provided on the first substrate surface 11, the dummy wafer 91 may be provided on the edge of the first substrate surface 11, and also be encapsulated by the first sealing layer 5 and the first plastic package layer 7 sequentially. Similarly, a passive element 93 such as a large inductor may also be provided on the first substrate surface 11 and encapsulated by the first sealing layer 5 and the first plastic package layer 7 sequentially. In this way, the dummy wafer 91 and the passive element 93 can effectively balance and relieve a shrinkage stress generated in response to the curing of the sealing material and the plastic package material, and prevent the first cavity device group 3 from being damaged by such shrinkage stress.

Meanwhile, isolating glue may also be provided between the lower surface of the passive element 93 and the first substrate surface 11 to prevent pins from being short-circuited.

Optionally, the dummy wafer 91 may also be provided in a non-edge area of the substrate 1, e.g., in a larger separation area between respective devices disposed in the center of the substrate 1, thereby balancing and relieving the stress caused by material curing.

The dummy wafer 91 may be made of a material such as silicon, ceramic or glass; or may be made of PCB, a substrate material or different plastic package material; or may also be made of metal, such as a metal frame made of a copper material.

Further, after step S05, the method further includes:

S08: thinning the first plastic package layer 7.

Further, after step S007, the method further includes:

S009: thinning the second plastic package layer 6.

Specifically, the first plastic package layer 7 and the second plastic package layer 6 may be ultimately thinned to reduce the thickness of the plastic package layer, reduce the deformation and warpage caused by material curing, and reduce the shrinkage pressure caused by further curing, thereby improving the overall reliability of the package structure.

The thinning process for the first plastic package layer 7 may be selected according to specific conditions, that is, the thinning process may not be performed. The thinning process for the second plastic package layer 6 is also optional. Meanwhile, at least part of the solder ball may also be exposed from the second plastic package layer 6 by means of laser drilling.

Optionally, the thinning process may be mechanical grinding and thinning, or laser thinning.

The package method for the cavity device group will be described completely.

In the package structure for the cavity device group, the package structure includes a substrate 1. The substrate 1 includes a first substrate surface 11 and a second substrate surface 12.

First, a passive element 93 such as a large inductor, which is sensitive to a mold flow pressure during plastic package, is provided on the first substrate surface 11 of the substrate, and a dummy wafer 91 is provided on the edge of the first substrate surface 11. Then, the first substrate surface 11 is covered with a first sealing layer 5, such that the first sealing layer 5 covers all devices on the first substrate surface 11. Next, a first plastic package layer 7 is provided on the surface of the first sealing layer 5, such that the first sealing layer 5 and the first plastic package layer 7 cover all the devices on the first substrate surface 11 sequentially. In addition, it needs to ensure that the flowability of a sealing material of the first sealing layer 5 is less than that of a plastic package material of the first plastic package layer 7.

Next, a second cavity device group 2 is provided on the second substrate surface 12, and a solder ball 821 is implanted into the second substrate surface 12 and thus electrically connected to a pad 121 on the second substrate surface 12. Then, a second sealing layer 4 is provided on the outer periphery of the second cavity device group 2 to encapsulate the second cavity device group 2. Finally, the second substrate surface 12 is covered with a second plastic package layer 6, the second plastic package layer 6 encapsulating the second sealing layer 4. In addition, the solder ball 821 may also be exposed through a laser drilling process, such that the entire package structure is electrically connected to other substrate 1 or structure through the solder ball 821.

In summary, according to the package structure for the cavity device provided by the present invention, the first cavity device group 3, which is sensitive to a mold flow pressure during plastic package, is provided on the first substrate surface 1. The first sealing layer 5 and the first plastic package layer 7 are sequentially provided on the outer periphery of the first cavity device group 3. The flowability of the sealing material of the first sealing layer 5 is relatively low, and less than that of the molding material of the first plastic package layer 7. In this way, in the plastic package process, the mold flow pressure generated by the first plastic package layer 7 is buffered and reduced in time by the first sealing layer 5 to effectively protect the first cavity device group 3 and prevent the first cavity device group 3 from being damaged by such mold flow pressure during the plastic package process, thereby improving the overall reliability and package yield of the entire package structure.

It should be understood that although the present invention is described in terms of embodiments in this description, not every embodiment includes only one independent technical solution. The statement mode of the description is merely for clarity, and those skilled in the art should regard the description as a whole. The technical solutions in various embodiments may also be combined properly to develop other embodiments that can be understood by those skilled in the art.

The series of detailed illustration listed above are merely for specifically illustrating the feasible embodiments of the present invention, but not intended to limit the protection scope of the present invention. Any equivalent embodiments or variations made without departing from the technical spirit of the present invention shall fall within the protection scope of the present invention.

What is claimed is:

1. A package structure for a cavity device group, comprising a substrate, the substrate comprising a first substrate surface and a second substrate surface which face each other, wherein a first cavity device group is provided on the first substrate surface; and the substrate further comprising:
a first sealing layer encapsulating the first cavity device group; and
a first plastic package layer encapsulating the first sealing layer, wherein the flowability of a sealing material of the first sealing layer is less than that of a plastic package material of the first plastic package layer.

2. The package structure for the cavity device group according to claim 1, wherein the first substrate surface is further covered with the first sealing layer.

3. The package structure for the cavity device group according to claim 1, wherein a second cavity device group and a second sealing layer are provided on the second substrate surface, and the second sealing layer encapsulates the second cavity device group.

4. The package structure for the cavity device group according to claim 3, wherein the second substrate surface is further covered with a second plastic package layer, the second plastic package layer encapsulates the second sealing layer, and the flowability of a sealing material of the second sealing layer is less than that of a plastic package material of the second plastic package layer.

5. The package structure for the cavity device group according to claim 1, wherein a dummy wafer is further provided on the edge of the first substrate surface, and encapsulated by the first sealing layer and the first plastic package layer sequentially.

6. The package structure for the cavity device group according to claim 1, wherein a passive element is further provided on the first substrate surface, and encapsulated by the first sealing layer and the first plastic package layer sequentially.

7. The package structure for the cavity device group according to claim 1, wherein an electrical and thermal conduction structure and a second plastic package layer are further provided on the second substrate surface, and at least part of the electrical and thermal conduction structure is encapsulated by the second plastic package layer.

8. A package method for a cavity device group, comprising the following steps:
providing a first cavity device group on a first substrate surface;
providing a first sealing layer on the outer periphery of the first cavity device group, such that the first cavity device group is encapsulated by the first sealing layer; and
performing plastic packaging on the first substrate surface to form a first plastic package layer, such that the first sealing layer is encapsulated by the first plastic package layer, wherein the flowability of a sealing material of the first sealing layer is less than that of a plastic package material of the first plastic package layer.

9. The package method for the cavity device group according to claim 8, wherein the step of “providing the first sealing layer on the outer periphery of the first cavity device group, such that the first cavity device group is encapsulated by the first sealing layer” specifically comprises:
providing the first sealing layer on the outer periphery of the first cavity device group and the first substrate surface, such that the first sealing layer covers the first substrate surface and encapsulates the first cavity device group.

10. The package method for the cavity device group according to claim 8, wherein prior to the step of “providing the first cavity device group on the first substrate surface” or after the step of “performing plastic packaging on the first substrate surface to form the first plastic package layer, such that the first sealing layer is encapsulated by the first plastic package layer, wherein the flowability of the sealing material of the first sealing layer is less than that of the plastic package material of the first plastic package layer”, the method further comprises:
providing a second cavity device group and a second sealing layer on the second substrate surface, such that the second cavity device group is encapsulated by the second sealing layer.

11. The package method for the cavity device group according to claim 10, wherein after the step of “providing the second cavity device group and the second sealing layer on the second substrate surface, such that the second cavity device group is encapsulated by the second sealing layer”, the method further comprises:
covering the second substrate surface with a second plastic package layer, such that the second sealing layer is encapsulated by the second plastic package layer, wherein the flowability of a sealing material of the second sealing layer is less than that of a plastic package material of the second plastic package layer.

12. The package method for the cavity device group according to claim 8, wherein after the step of “providing the first cavity device group on the first substrate surface”, the method further comprises:
providing a dummy wafer on the edge of the first substrate surface, such that the dummy wafer is sequentially encapsulated by the first sealing layer and the first plastic package layer.

13. The package method for the cavity device group according to claim 8, wherein after the step of “providing the first cavity device group on the first substrate surface”, the method further comprises:
providing a passive element on the first substrate surface, such that the passive element is encapsulated by the first sealing layer and the first plastic package layer sequentially.

14. The package method for the cavity device group according to claim 8, wherein after the step of “performing plastic packaging on the first substrate surface to form the first plastic package layer, such that the first sealing layer is encapsulated by the first plastic package layer, wherein the flowability of the sealing material of the first sealing layer is less than that of the plastic package material of the first plastic package layer”, the method further comprises:
thinning the first plastic package layer.

15. The package method for the cavity device group according to claim 11, wherein after the step of “covering the second substrate surface with the second plastic package layer, such that the second sealing layer is encapsulated by the second plastic package layer, wherein the flowability of the sealing material of the second sealing layer is less than that of the plastic package material of the second plastic package layer”, the method further comprises:
thinning the second plastic package layer.
